(19) United States
(12) Patent Application Publication
(10) Pub. No.: US 2021/0272885 A1
(43) Pub. Date: Sep. 2, 2021

(54) INTERPOSER HEAT SPREADER

(71) Applicant: Intel Corporation, Santa Clara, CA (US)

(72) Inventors: Kyle ARRINGTON, Gilbert, AZ (US); Aaron MCCANN, Queen Creek, AZ (US); Weston K. BERTRAND, Tempe, AZ (US)

(21) Appl. No.: 16/803,887

(22) Filed: Feb. 27, 2020

(51) Int. Cl. H01L 23/495; H01L 23/498; H01L 25/065

(52) U.S. Cl. CPC H01L 23/49568; H01L 25/0652; H01L 23/49827; H01L 23/49894

(57) ABSTRACT

Embodiments disclosed herein include electronic packages. In an embodiment, an electronic package comprises a package substrate and an interposer over the package substrate. In an embodiment, the interposer comprises a ceramic. In an embodiment, the electronic package further comprises a first die over the interposer and a second die over the interposer. In an embodiment, the first die and the second die are electrically coupled together by the interposer. In an embodiment, the electronic package further comprises an integrated heat spreader (IHS) over the first die and the second die.

### TECHNICAL FIELD

Embodiments of the present disclosure relate to semiconductor devices, and more particularly to interposer architectures for improved thermal performance in multi-chip packages.

### BACKGROUND

Thermal management of electronic packages is of growing importance. The importance of thermal management is increasing as the number of dies in each package increases (e.g., with multi-chip package (MCP) architectures, die stacking, etc.) and as the power consumption of the dies increase. Sometimes, thermal management is provided, at least in part, by an integrated heat spreader (IHS). The IHS is thermally coupled to a backside surface of the die by a thermal interface material (TIM). In this way, thermal energy easily propagates to the IHS from the die. However, in the case of stacked dies, the die stack results in a high thermal resistance in the vertical direction. As such, the thermal path across the TIM to the IHS from the backside of the die is not as effective in removing heat from the die stack.

Without a low thermal resistance path from the backside surface of the die, thermal energy is propagated into the underlying substrate. Traditional packaging substrates comprise organic materials. As such, the package substrate is a poor spreader of heat, and hotspots are formed below the die. Some packaging architectures have used an interposer between the package substrate and the die in order to minimize the generation of hotspots below the die. However, currently available interposers comprise silicon. While silicon is a better thermal conductor than the package substrate, it is still not adequate to mitigate hotspots in some applications.

### BRIEF DESCRIPTION OF THE DRAWINGS

FIG. 1A is a cross-sectional illustration of an electronic package with an interposer that comprises a thermally conductive ceramic with a first die and a second die over the interposer, in accordance with an embodiment.

FIG. 1B is a cross-sectional illustration of an electronic package with an interposer that comprises a thermally conductive ceramic and a first die and a second die over the interposer, where the second die comprises a plurality of stacked chiplets, in accordance with an embodiment.

FIG. 2A is a cross-sectional illustration of an electronic package with an interposer and a pedestal over the interposer, in accordance with an embodiment.

FIG. 2B is a cross-sectional illustration of an electronic package with an interposer and a pedestal over the interposer, where the pedestal is between a first die and a second die, in accordance with an embodiment.

FIG. 2C is a cross-sectional illustration of an electronic package with an interposer with stacked dies and stacked pedestals over the interposer, in accordance with an embodiment.

FIG. 3 is a cross-sectional illustration of an electronic package with an interposer that comprises a pedestal, where the interposer and the pedestal are a monolithic structure, in accordance with an embodiment.

FIG. 4A is a cross-sectional illustration of an electronic package with an interposer and an integrated heat spreader (IHS) that is supported by the interposer, in accordance with an embodiment.

FIG. 4B is a cross-sectional illustration of an electronic package with a monolithic interposer and pedestal architecture and an IHS that is supported by the interposer, in accordance with an embodiment.

FIG. 5 is a cross-sectional illustration of an electronic system that comprises an interposer that is formed with a thermally conductive ceramic, in accordance with an embodiment.

FIG. 6 is a schematic of a computing device built in accordance with an embodiment.

### EMBODIMENTS OF THE PRESENT DISCLOSURE

Described herein are electronic packages with interposer architectures for improved thermal performance in multi-chip packages, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, providing adequate thermal management for electronic packages is becoming an increasingly problematic engineering challenge, especially in multi-chip packages (MCPs) and stacked die architectures. In the case of stacked die architectures, thermal resistance through the thickness of the die is particularly limited. As such, conventional integrated heat spreader (IHS) architectures that interface with the backside surface of the dies are limited since the thermal resistance through the thickness of the dies is high. As such, hot spots in the underlying package substrate or interposer may be generated. The presence of hot spots makes it more likely that the junction temperature (Tⱼ) of the die is exceeded. This results in throttling of the die, damage to the die, or even failure of the die.

Accordingly, embodiments disclosed herein include thermal solutions that provide improved spreading of thermal energy in the interposer below the die. In that way an alternative cooling path to the IHS is provided. In some embodiments, the increased thermal spreading in the interposer is provided through the use of a material with a low thermal resistivity. For example, high thermal conductivity ceramics may be used as the interposer instead of traditional silicon substrates. In yet another embodiment, pedestals extending up from the interposer may interface with the IHS. Accordingly, a thermal path from the bottom of the die to the IHS is provided. That is, a thermal path may be provided from the bottom surface of the die, into the interposer, and up through the pedestal to the IHS. In these ways, embodiments disclosed herein provide improved thermal control of the electronic package and reduce the likelihood that the junction temperature Tⱼ is exceeded. This provides a more robust electronic package and reduces the need for throttling, which improves performance of the electronic package.

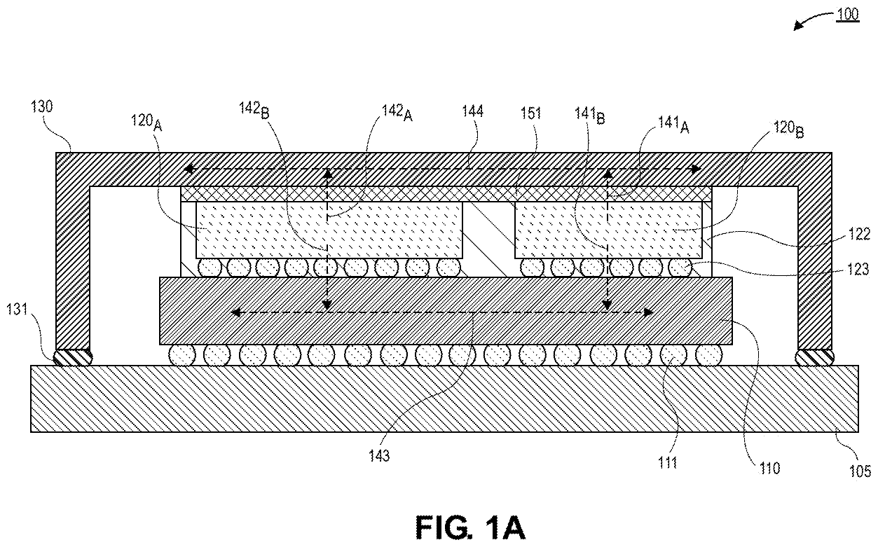

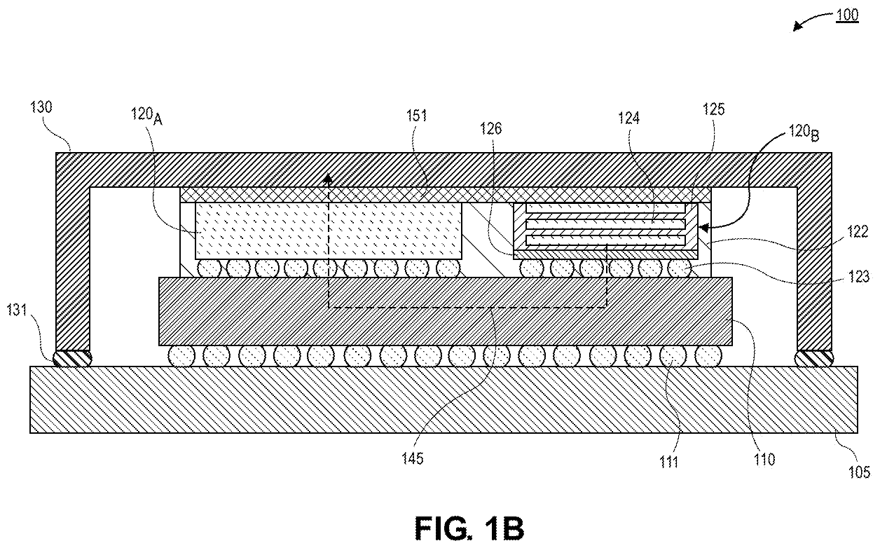

Referring now to FIG. 1A, a cross-sectional illustration of an electronic package 100 is shown, in accordance with an embodiment. In an embodiment, the electronic package 100 may comprise a package substrate 105. The package substrate 105 may comprise an organic material. The package substrate 105 may comprise a plurality of laminated layers of the organic material. In some embodiments, the package substrate 105 may comprise a core, while in other embodiments the package substrate 105 is a coreless package substrate 105. The package substrate 105 may comprise conductive features (e.g., traces, vias, pads, etc.) to provide electrical routing through the package substrate 105. The conductive features in the package substrate 105 are not shown for simplicity.

In an embodiment, the electronic package 100 may further comprise an interposer 110 attached to the package substrate 105. In an embodiment, the interposer 110 is attached to the package substrate 105 by interconnects 111. While the interconnects 111 in FIG. 1A are shown as solder balls, it is to be appreciated that any suitable interconnect architecture may be used to attach the interposer 110 to the package substrate 105. In an embodiment, the interposer may comprise conductive features to provide routing over the interposer 110. For example, the routing may connect a first die 120_{A} to a second die 120_{B}. Through interposer vias may provide a connection through the interposer 110 to electrically coupled interconnects 123 below the first and second dies 120_{A} and 120_{B} to the interconnects 111. In an embodiment, the interconnects 123 are shown as solder balls, however, it is to be appreciated that any suitable interconnect architecture may be used to attach the dies 120_{A} and 120_{B} to the interposer 110. For example, the interconnects 123 may comprise copper bumps or the like.

In an embodiment, the interposer 110 comprises a high thermal conductivity material. As used herein “high thermal conductivity” may refer to a thermal conductivity that is greater than the thermal conductivity of silicon. For example, high thermal conductivity may refer to a thermal conductivity that is approximately 1.5 W/cmK or greater. In an embodiment, the high thermal conductivity material may comprise a high thermal conductivity ceramic. For example, high thermal conductivity ceramics may include, but are not limited to silicon carbide, silicon nitride, aluminum carbide, aluminum nitride, beryllium oxide, and the like. Accordingly, the interposer 110 may comprise silicon and carbon, silicon and nitrogen, aluminum and carbon, aluminum and nitrogen, or beryllium and oxygen. That is, under material analysis (e.g., scanning electron microscopy (SEM) with energy-dispersive X-ray (EDX) capabilities), peaks corresponding to such elemental signatures may be present in order to differentiate the high conductivity interposer 110 from a standard silicon interposer. In some embodiments, the high conductivity interposer 110 may also have visual differences that distinguish it from a standard silicon interposer.

In an embodiment, the electronic package 100 may comprise a plurality of dies 120. For example, a first die 120_{A} and a second die 120_{B} are illustrated in FIG. 1A. In an embodiment, the first die 120_{A} may be different than the second die 120_{B}. For example, the first die 120_{A} may be a processor die (e.g., a central processor unit (CPU), a graphics processor unit (GPU), or the like) and the second die 120_{B} may be a memory die. The first die 120_{A} is communicatively coupled to the second die 120_{B} through traces on the interposer 110 (not shown for simplicity). In an embodiment, the first die 120_{A} and the second die 120_{B} may have different junction temperatures (Tⱼ). For example, the junction temperature Tⱼ of the first die 120_{A} may be higher than the junction temperature Tⱼ of the second die 120_{B}. For example, in the case of the first die 120_{A} being a processor die and the second die 120_{B} being a memory die, the junction temperature Tⱼ of the first die 120_{A} may be approximately 100° C. or higher, and the junction temperature Tⱼ of the second die may be approximately 90° C. or lower.

In an embodiment, one or both of the first die 120_{A} and the second die 120_{B} may be embedded within an insulating layer 122, such as an epoxy. That is, the sidewall surfaces of the first die 120_{A} and the second die 120_{B} may be contacted by the insulating layer 122. In an embodiment, the backside surfaces of the first die 120_{A} and the second die 120_{B} may be exposed to allow for thermal coupling to an integrated heat spreader (IHS) 130. In an embodiment, the interconnects 123 may further be surrounded by an underfill material (not shown).

In an embodiment, the electronic package 100 may further comprise an IHS 130. The IHS 130 may be a thermally conductive material. For example, the IHS 130 may be a metallic material, such as copper, aluminum, stainless steel, or the like. In an embodiment, the IHS 130 may comprise a core material that is plated. For example, the IHS 130 may comprise a copper core with a nickel plating. In an embodiment, the IHS 130 comprises legs that are supported by the package substrate 105. For example, the legs may be attached to the package substrate 105 by an adhesive 131.

In an embodiment, the IHS 130 is thermally coupled to the exposed backside surface of the first die 120_{A} and the second die 120_{B}. For example, a thermal interface material (TIM) 151 may be positioned between the IHS 130 and the backside surfaces of the first die 120_{A} and the second die 120_{B} in order to provide a low thermal resistance path. In an embodiment, a single layer of TIM 151 may extend across the backside surfaces of the first die 120_{A} and the second die 120_{B} as well as over the insulating layer 122. In other embodiments, discrete islands of TIM 151 may be disposed over each of the first die 120_{A} and the second die 120_{B}.

Several thermal paths are provided in the electronic package 100. For the first die 120_{A}, a first thermal path 142_{A} exits the backside surface of the first die 120_{A}, passes through the TIM 151 and enters the IHS 130. The high thermal conductivity of the IHS 130 allows the thermal energy to be spread through the IHS 130, as indicated by the arrow 144. A second thermal path 142_{B} is also provided for the first die 120_{A}. The second thermal path 142_{B} exits a bottom surface of the first die 120_{A} and enters into the interposer 110. Due to the high thermal conductivity of the interposer 110, the thermal energy is then spread through the interposer 110, as indicated by the arrow 143.

In an embodiment, the second die 120_{B} also comprises a pair of similar thermal paths. A first thermal path 141A exits the backside surface of the second die 120_{B}, passes through the TIM 151 and enters the IHS 130. The high thermal conductivity of the IHS 130 allows the thermal energy to be spread through the IHS 130, as indicated by the arrow 144. A second thermal path 141_{B} is also provided for the second die 120_{B}. The second thermal path 141E exits a bottom surface of the second die 120_{B} and enters into the interposer 110. Due to the high thermal conductivity of the interposer 110, the thermal energy is then spread through the interposer 110, as indicated by the arrow 143.

As opposed to architectures with an interposer with a higher thermal resistance (e.g., a silicon interposer), there is significant thermal spreading in the interposer 110 in accordance with embodiments disclosed herein. Therefore, there is a reduction in the presence of hotspots below the first die 120_{A} and the second die 120_{B} during operation of the electronic package 100.

Referring now to FIG. 1B, a cross-sectional illustration of an electronic package 100 is shown, in accordance with an additional embodiment. The electronic package 100 in FIG. 1B may be substantially similar to the electronic package 100 in FIG. 1A, with the exception of the construction of the second die 120_{B}. For example, the second die 120_{B} may be a die module that comprises a plurality of stacked dies 124 (sometimes called chiplets). The chiplets 124 may be embedded in an epoxy 125 or the like and be packaged over a substrate 126 (e.g., an organic package substrate). In an embodiment, the second die 120_{B} may be a memory die module, such as a high bandwidth memory (HBM) module.

Such constructions for the second die 120_{B} provide significant thermal challenges. Particularly, the stacked chiplet 124 construction significantly reduces the thermal conductivity through a thickness of the second die 120_{B}. For example, it becomes difficult to extract thermal energy through the backside surface of the second die 120_{B} into the IHS 130. As such, the primary thermal path is out the bottom of the second ide 120_{B} and into the interposer 110. Accordingly, a high thermal conductivity interposer 110 (e.g., a high thermal conductivity ceramic such as those described above) allows for improved heat spreading and reduces the generation of hotspots below the second die 120_{B}.

In an embodiment, the first die 120_{A} may still have a relatively high thermal conductivity through its thickness, and allows for thermal energy to be propagated out the backside surface into the IHS 130. This thermal path may also be used to remove thermal energy propagated into the interposer 110 by the second die 120_{B}. For example, a thermal path 145 from the second die 120_{B} to the IHS 130 is shown in FIG. 1B. As shown, the thermal path 145 exits the bottom surface of the second die 120_{B} and enters into the interposer 110. The thermal path 145 then spreads along the interposer 110 and is propagated up into the first die 120_{A}, and ultimately into the IHS 130. In this manner, the excess thermal energy is not confined to the interposer 110, and junction temperatures Tⱼ of the first die 120_{A} and the second die 120_{B} are not exceeded.

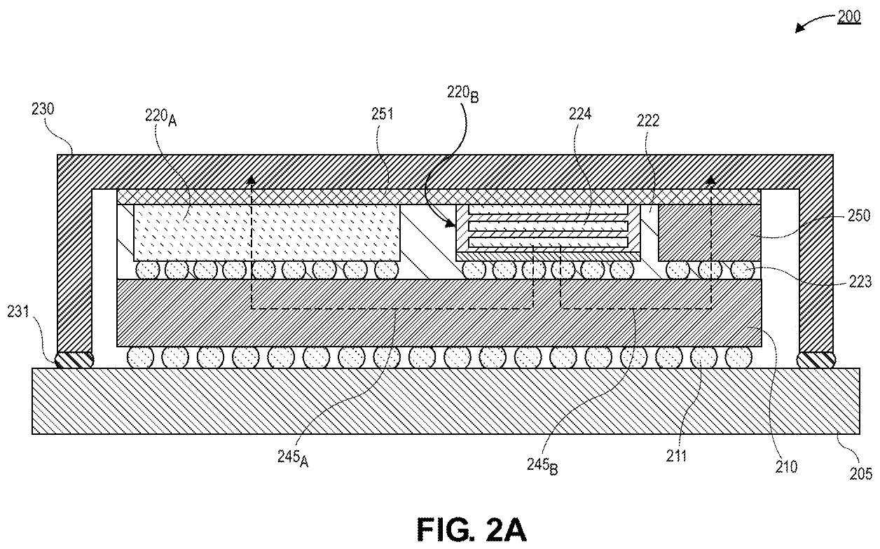

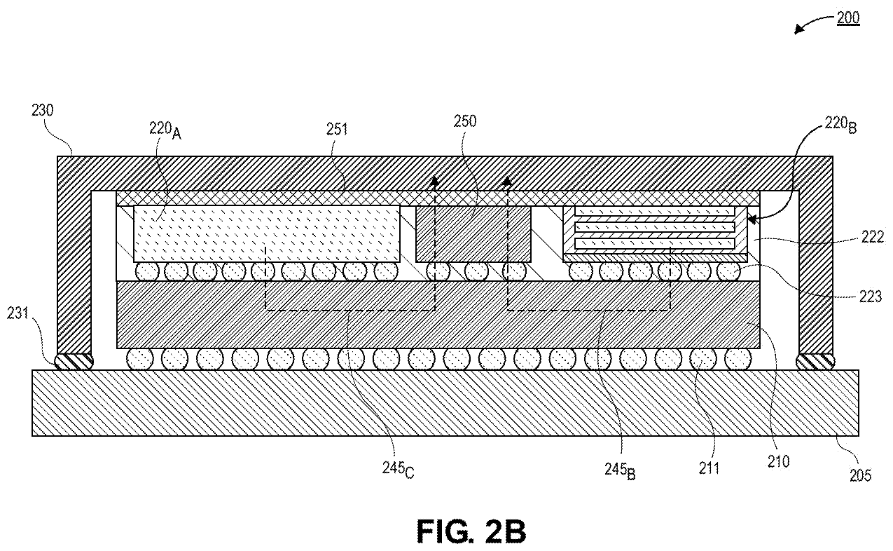

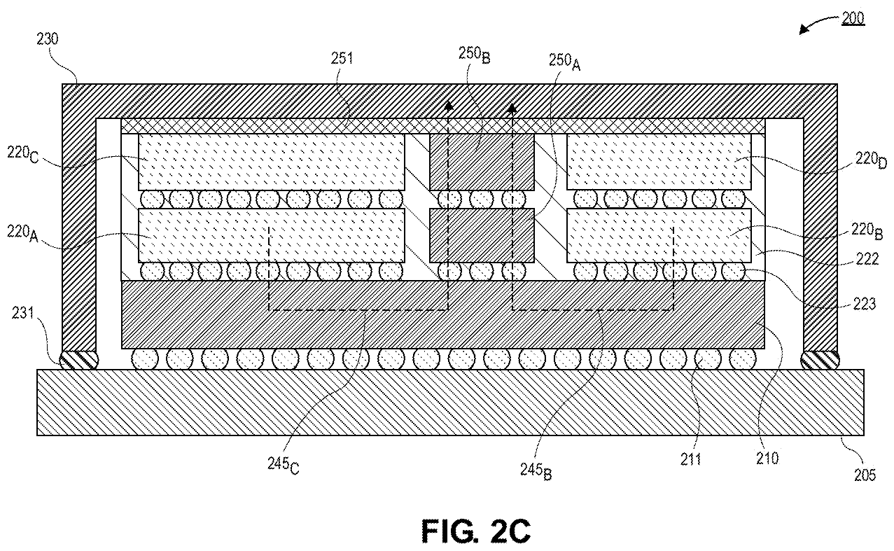

Referring now to FIG. 2A, a cross-sectional illustration of an electronic package 200 is shown, in accordance with an additional embodiment. In an embodiment, the electronic package 200 may comprise a package substrate 205 and an interposer 210 attached to the package substrate 205 by interconnects 211. The electronic package 200 may further comprise a first die 220_{A} and a second die 220_{B} that are connected to the interposer 210 by interconnects 223. In an embodiment, the second die 220_{B} may be a die module (e.g., a HBM module) that includes stacked chiplets 224. In an embodiment, the first die 220_{A} and the second die 220_{B} may be embedded in an insulating layer 222. The electronic package 200 may further comprise an IHS 230 that is thermally coupled to the first die 220_{A} and the second die 220_{B} by a TIM 251. The IHS 230 may be attached to the package substrate 205 by an adhesive 231. In some embodiments, the adhesive 231 is a thermally conductive adhesive to provide a direct thermal path between the package substrate 205 and the IHS 230.

In an embodiment, the electronic package 200 may further comprise one or more pedestals 250. For example, a single pedestal 250 is shown in FIG. 2A. In an embodiment, the pedestal 250 is attached to the interposer 210 with interconnects 223. An underfill (not shown) may surround the interconnects 223 below the pedestal 250. A backside surface of the pedestal 250 may be thermally coupled to the IHS 230 by the TIM 251. The pedestal 250 may be a block of material that has a high thermal conductivity. In some embodiments, the pedestal 250 may comprise the same material as the interposer 210. As such, a high thermal conductivity thermal path may extend from the interposer 210 to the IHS 230. In some embodiments, the pedestal 250 comprises no active circuitry. That is, electrical signals of the electronic package 200 do not pass over or through the pedestal 250.

The inclusion of such a pedestal 250 in the electronic package 200, therefore, provides second thermal path 245_{B} from the second die 220_{B} to the IHS 230. The first thermal path 245_{A} is similar to the thermal path 145 described in FIG. 1B. That is, the first thermal path 245_{A} may exit a bottom surface of the second die 220_{B}, extend along the interposer 210, enter the bottom surface of the first die 220_{A}, and pass into the IHS 230. The second thermal path 245_{B} may exit a bottom surface of the second die 220_{B}, extend along the interposer 210, enter the bottom surface of the pedestal 250, and pass into the IHS 230.

In an embodiment, the second thermal path 245_{B} has a lower thermal resistance than the first thermal path 245_{A}. As such, the thermal load will preferentially pass along the second thermal path 245_{B} and, therefore, reduces the thermal load that must pass across the first die 220_{A}. This reduces the thermal cross-talk between the first die 220_{A} and the second die 220_{B}, and may provide performance increases. For example, since the first die 220_{A} experiences a lower thermal load, it is less likely that the junction temperature Tⱼ of the first die 220_{A} is reached. The inclusion of a second thermal path 245_{B} also allows for more thermal energy to be removed from the second die 220_{B} and reduces the likelihood of exceeding the junction temperature Tⱼ of the second die 220_{B}.

Referring now to FIG. 2B, a cross-sectional illustration of an electronic package 200 is shown, in accordance with an embodiment. In an embodiment, the electronic package 200 in FIG. 2B may be substantially similar to the electronic package 200 in FIG. 2A, with the exception of the location of the pedestal 250. Whereas the pedestal 250 in FIG. 2A is to the right of the second die 220_{B} (i.e., the second die 220_{B} is between the first die 220_{A} and the pedestal 250), the pedestal 250 in FIG. 2B is to the left of the second die 220_{B} (i.e., the pedestal 250 is between the first die 220_{A} and the second die 220_{B}).

Moving the pedestal 250 between the first die 220_{A} and the second die 220_{B} may allow for further reductions in thermal cross-talk between the first die 220_{A} and the second die 220_{B}. As shown, the second thermal path 245_{B} remains substantially the same (i.e., passing from the second die 220_{B} through the pedestal 250 and into the IHS 230), and a third thermal path 245_{C} is provided. The third thermal path 245_{C} exits a bottom surface of the first die 220_{A}, extends along the interposer 210, into the pedestal 250, and into the IHS 230. That is, (at least some of) the thermal energy from the first die 220_{A} that may pass into the interposer 210 propagates up into the pedestal 250 instead of passing along the interposer 210 and under the second die 220_{B}. Similarly, (at least some of) the thermal energy from the second die 220_{B} that may pass into the interposer 210 propagates up into the pedestal 250 instead of passing along the interposer 210 and under the first die 220_{A}.

Referring now to FIG. 2C, a cross-sectional illustration of an electronic package 200 is shown, in accordance with an additional embodiment. The electronic package 200 in FIG. 2C may be substantially similar to the electronic package 200 in FIG. 2B, with the exception that there is a stacked die architecture. That is, the electronic package 200 may further comprise a third die 220_{C} that is stacked over the first die 220_{A}, and a fourth die 220_{D} that is stacked over the second die 220_{B}. In the illustrated embodiment, the die stacks each comprise a pair of vertically stacked dies 220. However, it is to be appreciated that other die stacking architectures may also be included. For example, a plurality of laterally adjacent dies 220 may both be stacked over the backside surface of a single die 220.

As noted above, vertically stacking dies 220, such as in the embodiment shown in FIG. 2C, results in a decrease in the thermal conductivity through the stack. That is, removal of thermal energy into the IHS 230 only through the backside surface of the die stack (e.g., the backside surface of the third die 220_{C} or the backside surface of the fourth die 220_{D}) may not be sufficient to provide adequate cooling. Accordingly, thermal energy is propagated from the die stacks down into the interposer 210.

Therefore, embodiments disclosed herein may include one or more pedestals 250 that provide a thermal bridge between the interposer 210 the IHS 230. For example, a pair of stacked pedestals 250_{A} and 250_{B} may be positioned over the interposer 210 and thermally coupled to the IHS 230 by the TIM 251. In an embodiment, the second thermal path 245_{B} from the second die 220_{B} to the IHS 230 may pass through the stacked pedestals 250_{A} and 250_{B}, and the third thermal path 245_{C} from the first die 220_{A} to the IHS 230 may pass through the stacked pedestals 250_{A} and 250_{B}.

In an embodiment, the stacked pedestals 250_{A} and 250_{B} may be substantially similar to the pedestal 250 described in FIGS. 2A and 2B. In an embodiment, the first pedestal 250_{A} may be attached to the interposer 210 by interconnects 223 and the second pedestal 250_{B} may be attached to the first pedestal 250_{A} by interconnects 223. In an embodiment, the interconnects 223 may be surrounded by an underfill (not shown).

While a pair of stacked pedestals 250 are shown, it is to be appreciated that one or more pedestals 250 may be used to provide a thermal bridge between the interposer 210 and the IHS 230. For example, a single pedestal with a thickness sufficient to match the standoff height of the stacked dies 220_{A} and 220_{C} may be used. Alternatively, the number of stacked pedestals 250 may be different than the number of stacked dies 220. For example, when there are two stacked dies (e.g., first die 220_{A} and third die 220_{C}), there may be three or more stacked pedestals 250. Furthermore, while the stacked pedestals 250_{A} and 250_{B} are illustrated as being between the die stacks (i.e., between the stack comprising the first die 220_{A} and the third die 220_{C} and the stack comprising the second die 220_{B} and the fourth die 220_{D}), it is to be appreciated that the stacked pedestals 250_{A} and 250_{B} may be positioned at any location above the interposer 210.

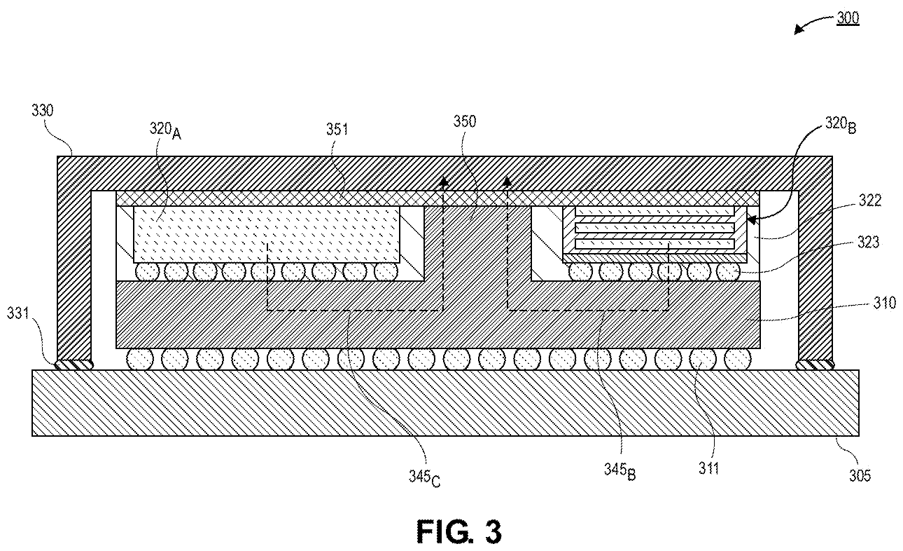

Referring now to FIG. 3, a cross-sectional illustration of an electronic package 300 is shown, in accordance with an embodiment. In an embodiment, the electronic package 300 comprises a package substrate 305 and an interposer 310 attached to the package substrate 305 by interconnects 311. A plurality of dies (e.g., a first die 320_{A} and a second die 320B) may be attached to the interposer 310 by interconnects 323. An insulating layer 322 may embed the first die 320_{A} and the second die 320_{B}. In an embodiment, an IHS 330 is disposed over the first die 320_{A} and the second die 320_{B} and attached to the package substrate 305 by an adhesive 331. In some embodiments, the adhesive 331 is a thermally conductive adhesive to provide a direct thermal path between the package substrate 305 and the IHS 330. The IHS 330 may be separated from the first die 320_{A} and the second die 320_{B} by a TIM 351.

In an embodiment, the interposer 310 may further comprise a pedestal 350. The pedestal 350 may extend out from a top surface of the interposer 310. That is, the interposer 310 and the pedestal 350 may be a monolithic structure formed from a single block of material. Forming the pedestal 350 and the interposer 310 as a monolithic structure of a high thermal conductivity material may improve the thermal performance of the electronic package. This is because there is one less interface between the interposer 310 and the IHS 330. Whereas the embodiments described above include attaching the pedestal 250 to the interposer 210 by interconnects, in the embodiment of FIG. 3, there is no such interface. This reduces the thermal resistance along the second thermal path 345_{B} and the third thermal path 345_{C}.

In an embodiment, a monolithic interposer 310 and pedestal 350 structure is shown with the interposer 310 between the first die 320_{A} and the second die 320_{B}. However, monolithic constructions of the interposer 310 and the pedestal 350 may also be formed with the pedestal 350 over any portion of the interposer 310 (e.g., the second die 320_{B} may be between the first die 320_{A} and the pedestal 350, similar to the embodiment shown in FIG. 2A). Additionally, a monolithic construction of the interposer 310 and the pedestal 350 may comprise a taller pedestal to accommodate stacked die architectures (such as the stacked die architecture illustrated in FIG. 2C).

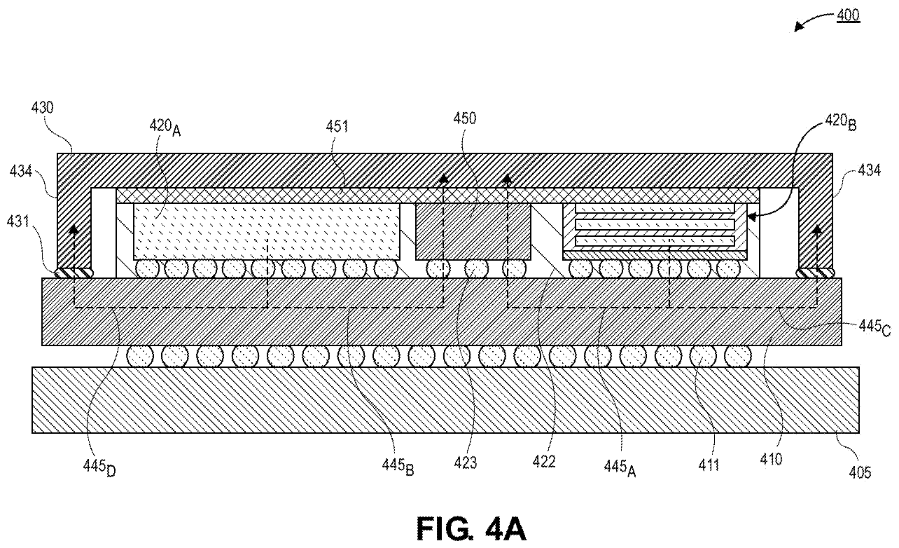

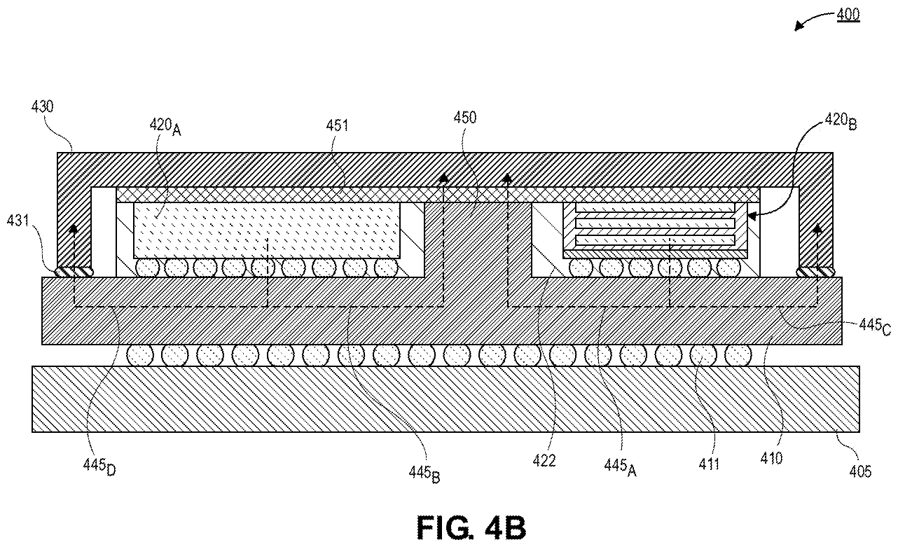

Referring now to FIG. 4A, a cross-sectional illustration of an electronic package 400 is shown, in accordance with an embodiment. In an embodiment, the electronic package 400 comprises a package substrate 405 and an interposer 410 attached to the package substrate 405 by interconnects 411. The electronic package 400 may further comprise a first die 420_{A} and a second die 420_{B} attached to the interposer 410 by interconnects 423. In an embodiment, the second die 420_{B} may be a die module (e.g., a HBM module). The first die 420_{A} and the second die 420_{B} may be embedded in an insulating layer 422. In an embodiment, an IHS 430 is disposed over the first die 420_{A} and the second die 420_{B}. A TIM 451 thermally couples the IHS 430 to the first die 420_{A} and the second die 420_{B}. In an embodiment, a pedestal 450 may be provided between the IHS 430 and the interposer 410.

In an embodiment, the pedestal 450 and the interposer 410 may comprise a high thermal conductivity material. As such, thermal energy from the bottom surfaces of the first die 420_{A} and the second die 420_{B} may easily propagate along the interposer 410 and pass up to the IHS 430. For example, a first thermal path 445_{A} propagates from the second die 420_{B} to the IHS 430 through the interposer 410 and the pedestal 450, and a second thermal path 445_{B} propagates from the first die 420_{A} to the IHS 430 through the interposer 410 and the pedestal 450.

In an embodiment, the IHS 430 may also be directly connected to the interposer 410. For example, legs 434 of the IHS 430 may be supported by the interposer 410. For example, the legs 434 may be attached to the interposer 410 by a thermal adhesive 431. As such, additional thermal paths from the first die 420_{A} and the second die 420_{B} to the IHS 430 are provided. For example, a third thermal path 445c may pass from the bottom surface of the second die 420_{B}, into the interposer 410, and up into the leg 434 of the IHS 430. Similarly, a fourth thermal path 445_{D} may pass from the bottom surface of the first die 420A, into the interposer 410, and up into the leg 434 of the IHS 430.

Referring now to FIG. 4B, a cross-sectional illustration of an electronic package 400 is shown, in accordance with an additional embodiment. In an embodiment, the electronic package 400 in FIG. 4B may be substantially similar to the electronic package 400 in FIG. 4A, with the exception that the interposer 410 and the pedestal 450 are formed as a monolithic structure. As noted above, the inclusion of a monolithic high thermal conductivity structure comprising the interposer 410 and the pedestal 450 allows for a reduction in the number of interfaces. Therefore, the thermal resistances of the first thermal path 445_{A} and the second thermal path 445_{B} are reduced.

In the embodiments illustrated in FIG. 4A and FIG. 4B, the pedestal 450 is positioned between the first die 420_{A} and the second die 420_{B}. However, it is to be appreciated that one or more pedestals 450 may be positioned at any location over the surface of the interposer 410. Additionally, the pedestal 450 may have any height, or may include stacked pedestals, to accommodate stacked die configurations.

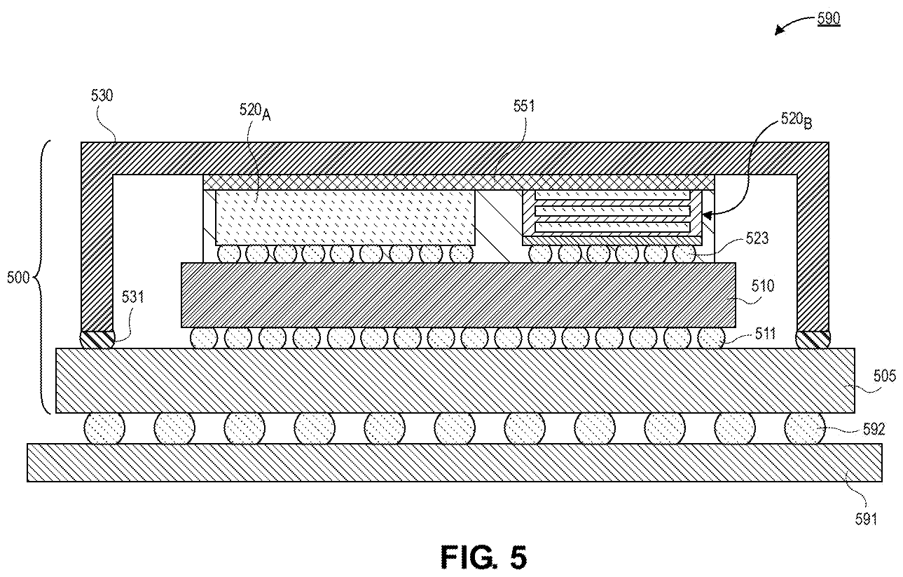

Referring now to FIG. 5, a cross-sectional illustration of an electronic system 590 is shown, in accordance with an embodiment. In an embodiment, the electronic system 590 may comprise a board 591 (e.g., a motherboard) and an electronic package 500 attached to the board 591 by interconnects 592. The interconnects 592 are shown as being solder balls. However, it is to be appreciated that the interconnects 592 may comprise any suitable interconnect architecture (e.g., sockets, wire bonds, etc.).

In an embodiment, the electronic package 500 may be substantially similar to any of the electronic packages 100, 200, 300, or 400 described above. In a particular embodiment, the electronic package 500 is shown as being substantially similar to the electronic package 100 illustrated in FIG. 1B. For example, the electronic package 500 may comprise a package substrate 505 and an interposer 510 attached to the package substrate 505 by interconnects 511. In an embodiment, a first die 520_{A} and a second die 520_{B} are attached to the interposer 510 by interconnects 523. The electronic package 500 may further comprise a TIM 551 that thermally couples the first die 520_{A} and the second die 520_{B} to an IHS 530. The IHS 530 may be attached to the package substrate 505 by an adhesive 531. In some embodiments, the adhesive 531 is a thermally conductive adhesive to provide a direct thermal path between the package substrate 505 and the IHS 530.

In an embodiment, the interposer 510 comprises a high thermal conductivity material. For example, the interposer 510 may comprise materials, such as, but not limited to, silicon carbide, silicon nitride, aluminum carbide, aluminum nitride, beryllium oxide, and the like. In the illustrated embodiment, there is no high thermal conductivity pedestal shown. However, it is to be appreciated that the electronic system 590 may further comprise such a pedestal, similar to the embodiments described above.

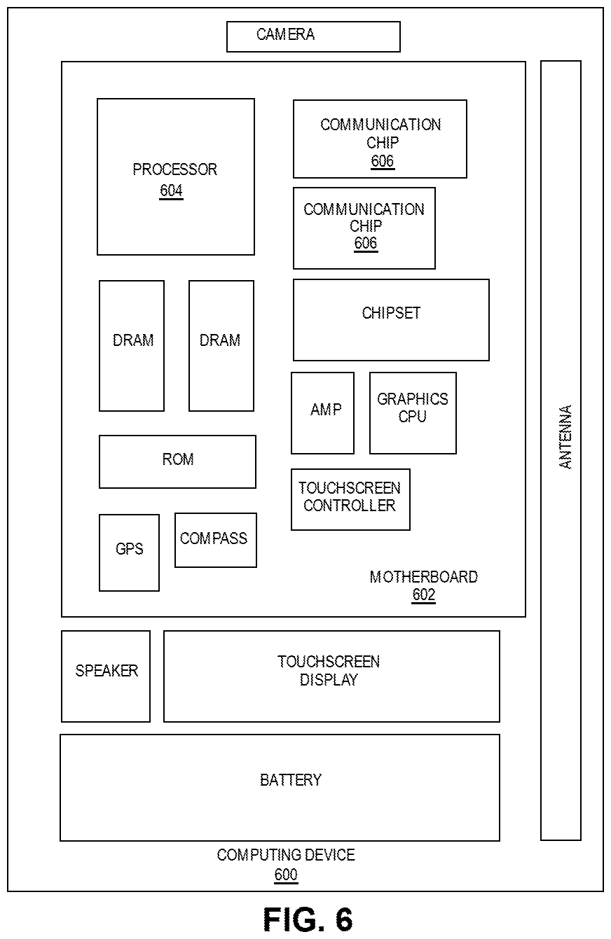

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor 604 may be part of an electronic package that comprises an interposer comprising a high thermal conductivity material, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip 606 may be part of an electronic package that comprises an interposer comprising a high thermal conductivity material, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate; an interposer over the package substrate, wherein the interposer comprises a ceramic; a first die over the interposer; a second die over the interposer, wherein the first die and the second die are electrically coupled together by the interposer; and an integrated heat spreader (IHS) over the first die and the second die.

Example 2: the electronic package of Example 1, further comprising: a pedestal over the interposer.

Example 3: the electronic package of Example 2, wherein the pedestal is between the first die and the second die.

Example 4: the electronic package of Example 2, wherein the pedestal is attached to the interposer by interconnects.

Example 5: the electronic package of Example 2, wherein the pedestal and the interposer are a monolithic structure.

Example 6: the electronic package of Example 2, wherein the pedestal is thermally coupled to the IHS.

Example 7: the electronic package of Examples 1-6, wherein the second die comprises a plurality of vertically stacked chiplets.

Example 8: the electronic package of Examples 1-7, further comprising a third die over the first die.

Example 9: the electronic package of Example 8, further comprising a fourth die over the second die.

Example 10: the electronic package of Examples 1-9, wherein the ceramic comprises silicon and carbon, silicon and nitrogen, aluminum and carbon, aluminum and nitrogen, or beryllium and oxygen.

Example 11: the electronic package of Examples 1-10, wherein the first die is a processor die and the second die is a memory die.

Example 12: the electronic package of Examples 1-11, wherein the IHS comprises supports that are attached to the package substrate.

Example 13: the electronic package of Examples 1-12, wherein the IHS comprises supports that are attached to the interposer.

Example 14: an interposer, comprising: a substrate with a first surface and a second surface, wherein the substrate comprises a thermally conductive ceramic material; a pedestal over the second surface of the substrate; and a plurality of through substrate vias (TSVs) through the substrate.

Example 15: the interposer of Example 14, wherein the pedestal and the substrate are a monolithic structure.

Example 16: the interposer of Example 14, wherein the pedestal is attached to the substrate by interconnects.

Example 17: the interposer of Examples 14-16, wherein the substrate comprises silicon and carbon, silicon and nitrogen, aluminum and carbon, aluminum and nitrogen, or beryllium and oxygen.

Example 18: the interposer of Examples 14-17, wherein the pedestal is adjacent to an edge of the substrate.

Example 19: the interposer of Examples 14-18, wherein the pedestal is set back from an edge of the substrate.

Example 20: a module, comprising: a ceramic interposer; a first die attached to the ceramic interposer, wherein the first die has a first thermal resistance; a second die attached to the ceramic interposer, wherein the second die has a second thermal resistance that is higher than the first thermal resistance; and a pedestal attached to the ceramic interposer.

Example 21: the module of Example 20, wherein the second die comprises a plurality of vertically stacked chiplets.

Example 22: the module of Example 20 or 21, further comprising: an integrated heat spreader (IHS) thermally coupled to the first die, the second die, and the pedestal by a thermal interface material.

Example 23: the module of Example 22, wherein a primary thermal path from the second die to the IHS is along the ceramic interposer and the pedestal.

Example 24: an electronic system, comprising: a board; a package substrate attached to the board; an interposer attached to the package substrate, wherein the interposer comprises a thermally conductive ceramic; a plurality of dies attached to the interposer; a pedestal extending away from the interposer and adjacent to the plurality of dies; and an integrated heat spreader (IHS) thermally coupled to the plurality of dies and the pedestal by a thermal interface material.

Example 25: the electronic system of Example 24, wherein the pedestal and the interposer are a monolithic part.

What is claimed is:

1. An electronic package, comprising:
a package substrate;
an interposer over the package substrate, wherein the interposer comprises a ceramic;
a first die over the interposer;
a second die over the interposer, wherein the first die and the second die are electrically coupled together by the interposer; and
an integrated heat spreader (IHS) over the first die and the second die.

2. The electronic package of claim 1, further comprising:
a pedestal over the interposer.

3. The electronic package of claim 2, wherein the pedestal is between the first die and the second die.

4. The electronic package of claim 2, wherein the pedestal is attached to the interposer by interconnects.

5. The electronic package of claim 2, wherein the pedestal and the interposer are a monolithic structure.

6. The electronic package of claim 2, wherein the pedestal is thermally coupled to the IHS.

7. The electronic package of claim 1, wherein the second die comprises a plurality of vertically stacked chiplets.

8. The electronic package of claim 1, further comprising a third die over the first die.

9. The electronic package of claim 8, further comprising a fourth die over the second die.

10. The electronic package of claim 1, wherein the ceramic comprises silicon and carbon, silicon and nitrogen, aluminum and carbon, aluminum and nitrogen, or beryllium and oxygen.

11. The electronic package of claim 1, wherein the first die is a processor die and the second die is a memory die.

12. The electronic package of claim 1, wherein the IHS comprises supports that are attached to the package substrate.

13. The electronic package of claim 1, wherein the IHS comprises supports that are attached to the interposer.

14. An interposer, comprising:
a substrate with a first surface and a second surface, wherein the substrate comprises a thermally conductive ceramic material;
a pedestal over the second surface of the substrate; and
a plurality of through substrate vias (TSVs) through the substrate.

15. The interposer of claim 14, wherein the pedestal and the substrate are a monolithic structure.

16. The interposer of claim 14, wherein the pedestal is attached to the substrate by interconnects.

17. The interposer of claim 14, wherein the substrate comprises silicon and carbon, silicon and nitrogen, aluminum and carbon, aluminum and nitrogen, or beryllium and oxygen.

18. The interposer of claim 14, wherein the pedestal is adjacent to an edge of the substrate.

19. The interposer of claim 14, wherein the pedestal is set back from an edge of the substrate.

20. A module, comprising:
a ceramic interposer;
a first die attached to the ceramic interposer, wherein the first die has a first thermal resistance;
a second die attached to the ceramic interposer, wherein the second die has a second thermal resistance that is higher than the first thermal resistance; and
a pedestal attached to the ceramic interposer.

21. The module of claim 20, wherein the second die comprises a plurality of vertically stacked chiplets.

22. The module of claim 20, further comprising:
an integrated heat spreader (IHS) thermally coupled to the first die, the second die, and the pedestal by a thermal interface material.

23. The module of claim 22, wherein a primary thermal path from the second die to the IHS is along the ceramic interposer and the pedestal.

24. An electronic system, comprising:
a board;
a package substrate attached to the board;
an interposer attached to the package substrate, wherein the interposer comprises a thermally conductive ceramic;
a plurality of dies attached to the interposer;
a pedestal extending away from the interposer and adjacent to the plurality of dies; and
an integrated heat spreader (IHS) thermally coupled to the plurality of dies and the pedestal by a thermal interface material.

25. The electronic system of claim 24, wherein the pedestal and the interposer are a monolithic part.
